(19) United States
(12) Patent Application Publication
(10) Pub. No.: US 2008/0223428 A1
(43) Pub. Date: Sep. 18, 2008

(54) All printed solar cell array

(76) Inventor: Eitan C. Zeira, Hollis, NH (US)

Correspondence Address: GROSSMAN, TUCKER, PERREAULT & PFLEGER, PLLC, 55 SOUTH COMMERICAL STREET, MANCHESTER, NH, 03101, US

(21) Appl. No.: 11/296,573

(22) Filed: Dec. 7, 2005

Related U.S. Application Data
(63) Continuation-in-part of application No. 11/109,365, filed on Apr. 19, 2005.
(60) Provisional application No. 60/563,496, filed on Apr. 19, 2004.

(51) Int. Cl. H01L 31/042; B05D 1/02; B41F 7/02; B41L 17/08; B41L 9/00

(52) U.S. Cl. 136/244; 136/252; 427/74; 101/129; 101/450.1; 101/170; 101/492

(57) ABSTRACT

The present invention relates to a method for producing a photovoltaic novelty item. Conductive polymer solutions and semiconductive oxide dispersions are formulated into inks that are laid down on top of one another to produce voltage and current when exposed to light. In addition, these inks may be printed on novelty items, such as magazine advertisements or greeting cards, connecting to printed light emitting graphics.

### CROSS REFERENCE TO RELATED APPLICATIONS

The present application is a continuation-in-part of U.S. patent application Ser. No. 11/109,365, filed Apr. 19, 2005, which claims the benefit of U.S. Provisional Application Ser. No. 60/563,496 filed Apr. 19, 2004, the teachings of which are incorporated herein by reference.

### FIELD OF THE INVENTION

The present invention relates to photovoltaic novelty items such as solar cells and a method for producing such. In particular this invention relates to a method of producing an all printed solar cell substrate, wherein the substrate is a novelty item.

### BACKGOUND

Photovoltaic or solar cells have been around for quite some time and have seen moderate success in the market. The current technology may use silicon as the base material. However, this product may not be ubiquitous in the market due to the high cost and fragility of the end product. The raw material may be expensive (same material as is used for computer chips) and may be like a thin sheet of glass that can easily break. This may increase the difficulty to process and use.

Dye-sensitized solar cells (U.S. Pat. Nos. 5,350,644; 5,525,440; 5,569,561; 6,350,946) may use nanometer sized particles (<20 nm) of titanium dioxide (TiO₂) as the key component of the cell. It may be coated onto non-fragile substrates and may be relatively inexpensive. It has been reported that TiO₂ in its anatase crystalline form may act as a strong electron acceptor upon exposure to UV radiation—so much so that one may smear this material on the inside surface of a beaker, fill it up with pond water, and when exposed to sunlight break down all organic matter to carbon dioxide and water. Without being bound to a particular theory, it is surmised that the UV activated anatase “grabs” electrons from the organic molecules, thus breaking their bonds down to the highest level of binding energy (CO₂ and H₂O).

Titanium dioxide by itself only absorbs light in the UV region of the spectrum and thus does not make full use of the available solar energy. It has been reported that by dipping a TiO₂ coated substrate in a dye solution, the dye may adsorb onto the surface of the TiO₂ particles. These adsorbed dye molecules may absorb much more of the sunlight radiation and readily donate their valence electrons to the activated anatase particles, creating a high efficiency donor acceptor couple. Thus the titanium dioxide may be an N-type electron acceptor and the sensitizing dye may be a P-type electron donor.

Electron replenishment of the oxidized dye molecules may be facilitated through immersion in an electrolyte that is in contact with a counter electrode. Upon illumination of such a cell by solar radiation, an electron may be injected from the dye into the TiO₂ layer followed by a hole transfer to the electrolyte. The electrons may be collected by the conducting substrate, while the holes in the form of oxidized ions may diffuse to the counter electrode where they may be reduced. This may complete the circuit of dye-sensitized solar cells (DSSC).

The construction of a DSSC may be as follows: glass substrate/transparent conductive coating/sintered anatase particle layer/adsorbed dye layer/redox couple electrolyte/metal layer electrode. Voltage and current may be produced between the transparent conductive coating and the metal electrode. Light may shine into the cell through the glass side. Depending on the materials used, these cells may be 5-10% efficient and may be cheaper than silicon cells.

There are several issues with these cells that may hinder use in the market. First and foremost is the use of liquid electrolyte. Electrolyte may cause leaks, may require that there be a gap in the cell to fill the liquid, and may form dendritic growth over time which may short the cell. Furthermore, a liquid-filled product may not be conducive to mass manufacturing.

The second issue is the possible need for high temperature sintering of the TiO₂ layer. The TiO₂ layer is sintered at 500° C., which is costly, and prevents using plastic substrates. This limits the type of substrate that may be used. The use of a glass substrate may not offer any advantage over the current silicon cells, and may also be a hindrance to mass manufacturing since may have to be done piece by piece or in batch mode manufacturing.

The third issue with the above cell is the manner in which the dye may be incorporated into the structure—it may need to be a thin layer that covers the entire surface of all the exposed TiO₂ particles. This may be accomplished by dipping the TiO₂ layer into a solution of the dye for a few hours so that the dye molecules from the solution stick to the layer and uniformly cover all the exposed surfaces.

To mass produce printed solar panels, the three issues mentioned above need to be resolved: for example, the TiO₂ layer may preferably be formed at temperatures compatible with plastic substrates (i.e. <250° F.); the liquid electrolyte may preferably be replaced with a solid layer that can conduct holes efficiently; and finally, the sensitizer layer may be coated rather than adsorbed through a dipping process.

There are numerous prior art patents and pending applications in the field of photovoltaics. These patents include but are not limited to the following.

Sichanugrust et. al. U.S. Pat. No. 5,133,809 claim a process for manufacturing a photovoltaic device via printing the top electrode, however, the bottom layers are shaped via laser ablation of a vacuum metallized transparent conductor and semiconductor layers which are full coats and not printed. Nakagawa et al. U.S. Pat. No. 6,080,928 claim a method of fabricating a photovoltaic array via grooves that separate the cells from each other. The layers are also not printed.

Nitta et. al. U.S. Pat. No. 4,645,866 claim a process for manufacturing a photovoltaic device by providing an isolation wall to separate individual cells. These cells and subsequent conductive connection sections are coated and not printed. Lian et al in U.S. patent application 2003/0188776 claim a flexible solar panel to energize a smart card or greeting card. The panel is produced separately by a coating method and then integrated into the card. In addition, the driven electronics are all mounted devices, not printed.

Similarly, U.S. Pat. Nos. 4,574,160 4,726,849 4,808,242 5,032,527 5,041,391 6,409,893 6,706,961 and patent applications 20030132498, 20040139999,20050000565 all speak to printing one or several components of a solar panel.

### SUMMARY OF THE INVENTION

An aspect of the present invention relates to a photovoltaic novelty item. The photovoltaic novelty item comprises a substrate; a solar cell disposed on the substrate, wherein the solar cell comprises a conductor ink, an electron acceptor ink contacting the conductor ink, an electron donor ink contacting the electron acceptor ink, a conductor ink contacting the electron donor ink, and a collector ink contacting the conductor ink; and an light emitting printed graphics in communication with the solar cell wherein the solar cell is a novelty item.

Another aspect of the present invention relates to a method for providing a photovoltaic novelty item. The method comprises providing a substrate, wherein the substrate is a novelty item, providing an light emitting printed graphics on said substrate; providing a conductor ink; providing an electron acceptor ink; providing an electron donor ink; providing a conductor ink; providing a collector ink; and disposing on the substrate the conductor ink; the electron acceptor ink contacting the conductor ink; the electron donor ink contacting the electron acceptor ink; the conductor ink contacting the electron donor ink; and the collector ink contacting the conductor ink to form a solar cell. The light emitting printed graphics are in communication with the solar cells. The substrates are novelty items.

### BRIEF DESCRITIPTION OF THE DRAWING

These and other features, aspects, and advantages of the present invention will be better understood when the following Detailed Description is read with reference to the accompanying drawings wherein:

FIG. 1 is a side view of an embodiment of the present invention relating to a printed solar cell stack.

FIG. 2 is a side view of an embodiment of the present invention relating to printed solar stacks connected in series by providing a printed insulator line with a conductive line on top of it from the top of one cell to the bottom of the adjacent cell.

FIG. 3 is a side view of another embodiment of the present invention relating to printed stacks interconnected in series by printed interconnects and showing the electrode connection of the positive and negative terminals.

FIG. 4 is a depiction of an embodiment of the present invention relating to a printed photovoltaic array where the parallel rows of series connected stacks are shown. The printed bus bars at both ends serve as the electrode terminals.

FIG. 5 is a depiction of an embodiment of the present invention relating to printed solar cell applied to a printed advertisement including light emissive graphics.

FIG. 6 is an embodiment of the present invention relating to an art work design used to create the image cylinder, screen or stencil to print the first layer of a printed solar cell stack. Depending on the configuration it may be either the anode or the cathode of the cell.

FIG. 7 is an embodiment of the present invention relating to an art work design used to create the image cylinder, screen or stencil to print the second layer of the a printed solar cell stack. Depending on the configuration it may be either the hole conductor or the n-type material of the cell.

FIG. 8 is an embodiment of the present invention relating to an art work design used to create the image cylinder, screen or stencil to print the third layer of a printed solar cell stack. It may be the p-type or electron donating material of the cell.

FIG. 9 is an embodiment of the present invention relating to an art work design used to create the image cylinder, screen or stencil to print the fourth layer of a printed solar cell stack. Depending on the configuration it may be either the hole conductor or the n-type material of the cell.

FIG. 10 is an embodiment of the present invention relating to an art work design used to create the image cylinder, screen or stencil to print the insulator layer for the interconnections of a printed solar cell stack.

FIG. 11 is an embodiment of the present invention relating to an art work design used to create the image cylinder, screen or stencil to print the interconnections of a printed solar cell stack.

FIG. 12 is an embodiment of the present invention relating to a light emitting printed graphics in communication with a solar cell.

### DETAILED DESCRIPTION

The present invention relates to a photovoltaic cell and a method of providing a photovoltaic cells consisting of multiple layers of relatively inexpensive inks that may be laid down on any substrate by simple coating and printing equipment. The substrates may be novelty items such as sundries, greeting cards, wrapping paper, packaging, bags, advertisements, advertisement goods, magazine graphics, labels, brochures, signs, etc.

Furthermore, these cells may be printed in isolated stacks and then connected to each other via printed interconnects to create an all printed solar panels. No special equipment, handling, or vacuum may be required. The inks may be printed using standard printing presses on a web or alternatively printed directly onto objects using spray painting or screen-printing.

In one embodiment the present invention relates to creating a printable power source which may enable portable power sources that can be laminated or printed directly onto electric and electronic devices. Another embodiment of the present invention relates to charging batteries or to powering a device in well-lit conditions. For example, electrified fences to herd cattle may use panels instead of recharging batteries or batteries that need constant replacement. Road signs, off grid lighting, water pumps etc. may all use re-charging capabilities and may not be restricted to the size of the panel used. Electronic equipment such as lap top computers, CD walkman, cell phones, PDAs, calculators etc., may have the solar panels printed directly on their cases to recharge their batteries. The present invention may also be used to print photovoltaic stickers that may be used to charge batteries in flashlights, walkmans, laptops, phones etc. Large coating operations could print wide rolls of this product for homes, cars, greenhouses, barns, street signs and billboards etc.

The present innovation also relates to material processing in providing specialty inks and manufacturing methods to deposit the inks using a number of methods and configurations. Various printing methods have been shown to work using these inks and manufacturing processes.

The present invention is also directed to a method that may enable high speed roll-to-roll manufacturing of printed solar panels. The layers used may be coated or printed with solutions and dispersions made materials or equipment that already exists. Specifically, this equipment may include printing presses or gravure coaters. Applications of the present invention may include, but are not limited to, stickers which may be applied on the back of a lap top computer cover to charge its batteries. A wide web roll used as roofing material to electrify a home or nailed to a tree or post and used to charge up an electric fence to contain herds or run a water pump, which then may be rolled up and stored when not needed.

In another embodiment, the present invention may relate to printed solar cell arrays used to energize or turn on light emitting printed graphics for the purposes of advertisement in magazines, packaging, brochures, signs and the like. The solar array cells may be used to turn on light emitting diodes printed in graphics, such as for the purpose of drawing attention to the printed surface.

The printed solar arrays may be used on card stock or greeting cars, wrapping paper, advertisements in magazines, various forms of packaging (e.g. beer, cereal, tooth paste), shopping bags, temporary signs (e.g. “Yard Sale” signs, etc.), for warning labels (e.g. “Hot” labels), sun screen application, perfume labels, survival gear, etc. to power light emitting printed graphics on these novelty items. Furthermore, the printed solar arrays may be used so that when a product is removed from its packaging, (e.g. removing a perfume bottle from the box,) the solar cell on the product may be energized. The printed solar array may also be provided as a solar panel including a cover sheet. The cover sheet may be separated (i.e. peeled off) to activate the cell.

### The TiO₂ Layer

DSSC processes may sinter the TiO₂ layer so that the TiO₂ particles may touch and join each other so electrons may be able to flow from the particles to the collection electrode. If they were not conjugated in some manner, then each particle may grab an electron from an adjacent dye molecule but may not be able to transfer the electron outside the cell, and therefore, would not be able to generate electricity. The high sintering temperature may slightly soften the TiO₂ particles so the particles may stick together, providing conjugation. Thus an electron generated at the outer most particles in the layer may diffuse from particle to particle and reach the substrate where it may be collected.

In one embodiment of the present invention, a hybrid binder-particle combination may be employed that when cross-linked may shrink to push the particles together and force the inter-particle conjugation by mechanical rather than thermal means. Careful selection of an appropriate binder system and concentration along with the TiO₂ particles plus exposure to UV radiation may bring about conjugation that cross-links the binder system. The processing parameters (e.g., the process window) may be fairly wide in a short period of time.

### The Solid Electrolyte

DSSC may use a redox couple electrolyte as the hole conductor. For example, an iodine based electrolyte or I₂⁻/I₃⁻ redox couple may be used. LiI and I₂ in an appropriate solvent may be one such example but there are many others that have been used as well. The electrolyte may function as follows.

The dye/titanium couple may be immersed in the electrolyte. When an electron is injected from the dye to the titanium oxide particle, an Iodine ion (I₂⁻) may donate one of its electrons to the hole in the dye to become an oxidized ion (I₃⁻). This ion may diffuse to the counter electrode, which may be platinum, to get reduced back to the I₂⁻ form.

The rate at which the ions diffuse to the counter electrode may be critical to the proper operation of the cell. If the diffusion rate is too slow in comparison to the dye/titanium oxide exchange rate, an excess of I₃⁻ ions may occur. This may screen the oxidized dye molecules from the I₂⁻ ions and may therefore slow down the replenishment of electrons to the oxidized dye molecules. This may reduce the overall current of the cell but may leave dye molecules in the oxidized state too long and thus may cause some of them to break down irreversibly and shorten the life of the cell.

Therefore the availability of electrons to re-reduce the dye molecules may be a requisite for proper operation. The source of these electrons may be the counter electrode and the electrolyte may be the medium the electrons have to traverse to reach the dye molecules. For the case of liquid electrolytes the governing step may be the ion diffusion rate, which may be in the range of 104 cm²/sec.

In one embodiment of the present invention, conjugated polymers may be used to perform the function of the electrolyte described above. Conjugated polymers may be organic based molecules that can conduct electricity. Without being bound to any particular theory, conjugated polymers may have the orbitals of adjoining atoms on the backbone of the polymer merge into a single long orbital that spans the length of the entire polymer chain. Hence the name conjugated polymers. Some of these polymers may be fast hole conductors providing mobility as high as 10⁻ cm²/Vsec, which may be up to approximately 10-1000 times faster than the ion diffusion rate in liquid electrolytes. These polymers may be formulated into solid coatings and may be used as coatings to shuttle the electrons from the counter electrode to the sensitizer molecules.

### The Sensitizer Layer

Dip coating of the sensitizer dye to the titanium dioxide layer, may present a problem for high volume continuous roll-to-roll processing. To apply a monolayer of the dye on all of the surfaces of the TiO₂ particles, the glass coated substrate may be by dipped in a dilute ethanol solution of the dye for several hours. This may be followed by an ethanol rinse to ensure removal of any excess dye from the surface. These dye molecules may not be conductive and extra layers of the dye may insulate the oxidized dye molecules that are in contact with the TiO₂ particles and may prevent them from being reduced by the ions in the electrolyte.

The dye molecules may be eliminated or replaced with semi-conductor polymers that do not have to be present as a monolayer because they conduct electrons. Semi-conductor polymers may be good electron donors and may absorb a significant portion of the solar spectrum.

The present invention may enable wide format high volume roll-to-roll manufacturing using coating and printing equipment. Multi-station printing presses may also be able to manufacture this product. Devices such as printers may also print solar panels along with graphics and phosphorescent coatings to make light emitting labels.

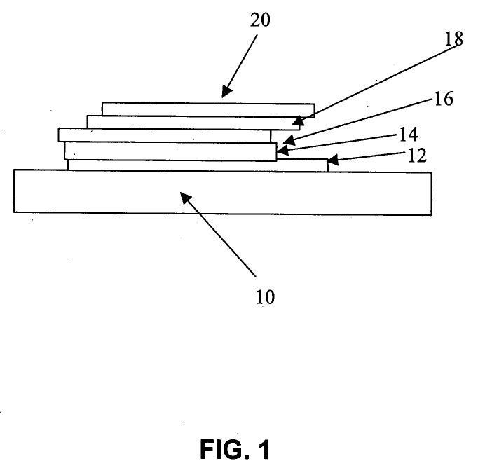

An exemplary embodiment of the present invention, a five layer coated product that functions as a photovoltaic cell, is illustrated in FIG. 1. As depicted in FIG. 1, the substrate 10 may be a polymer material, such as a polyester, including PET, polycarbonate or acrylic. Furthermore, the substrate may be media (i.e., paper goods including cardstock, brochures, packaging materials, newspaper, etc.), fabric, films (including the polymer materials disclosed herein), etc. The anode 12 may be a dispersion of nanometer sized transparent conductor material. The n-type semi-conductor 14 may be a wide band gap oxide dispersion ink. The p-type layer 16 may be a semi-conductor conjugated polymer or semi-conducting dye solution. The hole conductor 18 may be a semi-metal material with high electron mobility which may be a small particle dispersion ink. The cathode 20 may be a high conductivity metal dispersion ink. All layers may be coated using draw down equipment such as Meyer rod and Gravure hand rollers. A cell of this construction may produce 700 mV and 200μA/cm² when exposed to 100 mW/cm² of a sun simulator light source.

Making the dispersion inks may include the use of material processing equipment such as pre-dispersion mixing (Turbomill Mirodor Italy) and bead mill grinding (Netszch Lionville Pa.) to properly disperse the particles in the binders and vehicles that make up the inks. Proper dispersion may be measured via a particle size analyzer (Horiba 2000 Horiba Japan). In one exemplary embodiment, for illustrative purposes only, a D50 of 0.5 μm or less may be used as a dispersion allowing for the inks to be printed. Once the ink is properly dispersed its viscosity may be modified with additions of rheological modifiers to suit the printing method it is intended for.

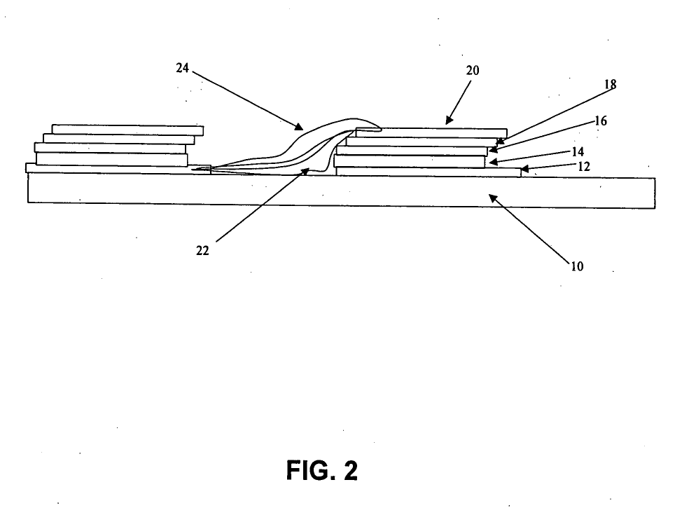

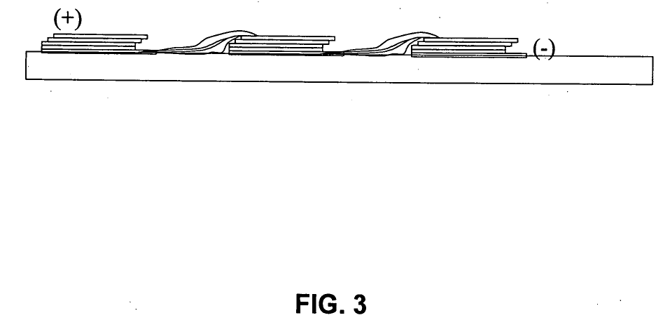

The inks may be used to print isolated cells and print connections in series and parallel designs to produce sufficient voltages and currents required by commercial applications. To increase voltage output, separated cells may be connected in series. Thus the series design may have strings of cell stacks connected to each other in a series configuration i.e. cathode-to-anode-to-cathode-to-anode as shown in FIG. 2. The insulator 22 may be printed between stacks to prevent shorting. The interconnection 24 may then be printed on top of insulator 22 to connect two neighboring cells in series. The series printed interconnects may then be applied to a printed row of stacks as shown in FIG. 3. The number of interconnects in a row may determine the overall row's voltage; which may be attained between the plus and minus terminals of the series.

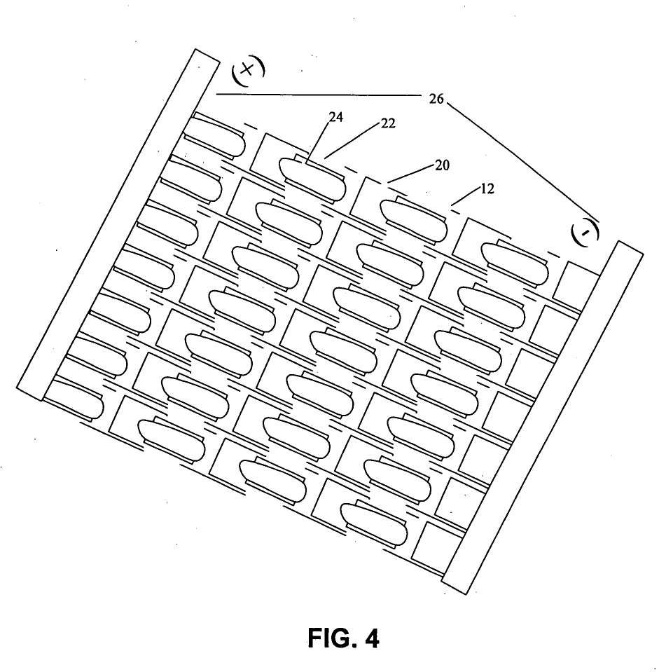

The parallel aspect of the design may comprise rows as illustrated in FIG. 4. The series strings may be arranged in parallel and connected together at each terminus, i.e. all the anodes may be connected together and all the cathodes may be connected together. Although each individual string may carry a relatively small current, the collection point or bus line 26 may carry a high current. This may provide an all printed solar panel having a high voltage and current available at terminals provided by printed bus lines at the edges of the web. Thus in a manufacturing process of printing solar panels using the present invention, the width of the web may determine the voltage of the panels, i.e. how many solar cell stacks may be printed in series along the width of the roll. The roll may then be cut at different lengths, which may determine the amount of current, and therefore, the overall power of the panel.

Referring back to FIG. 1, ink 12 may be a transparent conductor. It may be capable of transmitting between 50-95% of sunlight and any increment therebetween, including 80-85%, 85-90%, etc. and provide conductivity that may be greater than 100 Ohms per square. It may be made of particles that are less than 100 nm in size, and including particles less than 50 nm. Indium tin oxide and silver are just two examples of materials that may be used as a transparent conductor.

Ink 14 may be described as a wide band gap material, that is it may be designed to absorb the UV part of the solar spectrum and function as the electron acceptor. It may be composed of semi-conducting metal oxides having a band gap greater than approximately 2.5 eV including a band gap greater than 3 eV. Zinc oxide, niobium oxide and titanium oxide are examples of such materials. The size of the oxide particles may be less than 50 nm, including particles less than 20 nm.

Ink 16 may be the absorber layer. It may be designed to absorb the visible part of the spectrum and function as the electron donor. It may be made of a solution of p-type conducting materials such as conjugated polymers and dyes. Poly (3-octylthiophene) and copper phthalocyanine may be examples of such materials.

Ink 18 may be a hole conductor material, and may be designed to shuttle electrons from the counter electrode to the electron donor material. It may be made of materials that conduct electricity via electron hopping mechanism. Its conductivity may be between that of a semi conductor and a conductor. It may be referred to as a semi-metal. The conductivity may be in the range of 10² to 10³ Ω-cm⁻¹ with mobility in the range of 10⁻¹ cm²/volt second. Pentacene, polythiophene, and carbon black are some examples of suitable materials.

Ink 20 may serve as the collector or electrode. It may be designed to carry current and may incorporate highly conducting metal flakes, such as silver, gold, and graphite are examples of such materials. This ink may also be used as interconnection 24 between cells as shown in FIG. 2, and bus line 26 in FIG. 4.

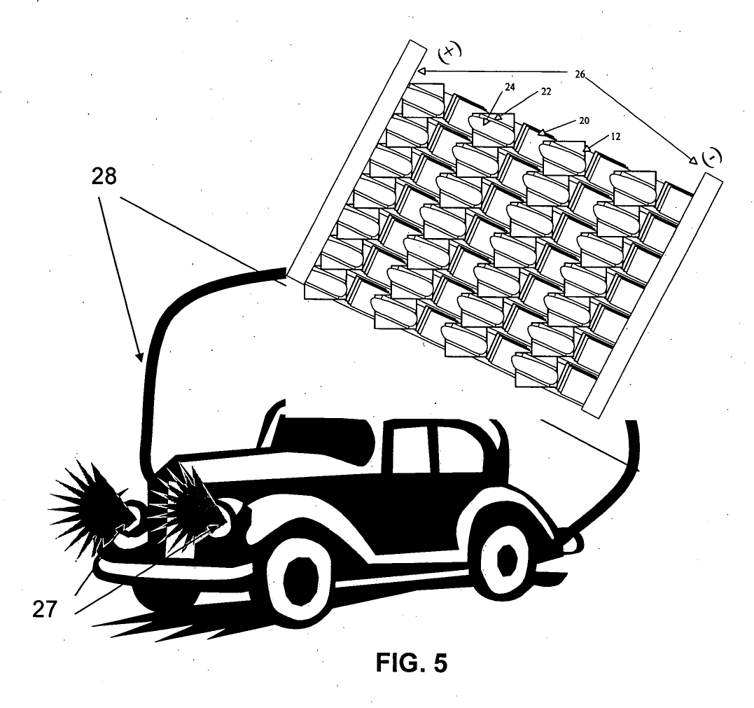

FIG. 5 depicts an exemplary application where the solar array may be printed along with a printed advertisement that contains electroluminescent ink 27 in some of its areas. Printed silver ink connectors 28 may be printed between the solar array and the emissive ink area to supply it with electricity. When the solar array is exposed to light, it supplies the electroluminescent material with voltage that may stimulate it to emit light. Another exemplary application may be by placing the solar array in an item where the item may be stored in a box. When the item is removed from the box, the solar array cell may be activated. Furthermore, the solar array cell may have a peel away sheet or covering that may present the cell from receiving light and become activated. When the peel away sheet or covering is removed the solar array cell may be activated.

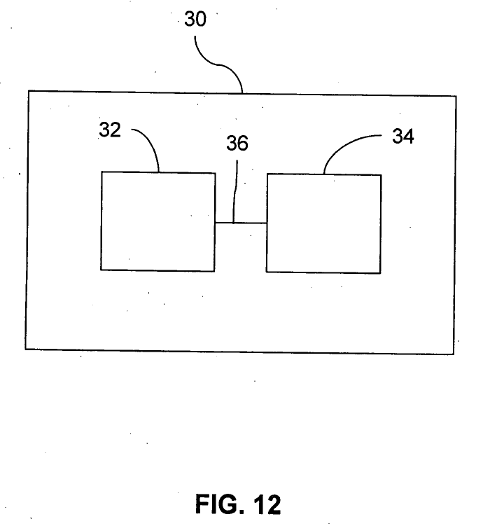

In an exemplary embodiment of the present invention, illustrated in FIG. 12, electrically functional printing matter 32, such as light emitting printed graphics, may be printed on a substrate material 30. The light emitting printed graphics may form light emitting graphics in various applications described herein. The solar cell arrays 34 contemplated herein may be printed on the substrate 30 as well. The electrically functional printed matter may be connected to the printed solar cell arrays using printed electrodes 36, such as illustrated in FIG. 2.

In one embodiment of the present invention, the above materials may be dispersed and ground with dispersing agents and binders well known in the art to create the inks required. The inks may then be printed in the prescribed patterns to create all printed solar panels.

Prior solar cells may produce 0.4-0.8V and about 20 mA/cm². Many electric and electronic devices may run on 3 V-12V and 20-500 mA. A consumer electronic device may use 1-4 rechargeable batteries. Different power panels may be printed to suit specific applications. For example, to charge batteries for a Walkman CD (uses two AA) requires more than 3V i.e. about 4V and about 40 mA. Thus a 4V 40 mA array may be printed and used to charge two AA batteries. This by no means suggests limitations to product types nor to markets. For the purpose of illustration only, the following are examples of the printing equipment and inks that may be employed.

It should be appreciated that the inks described in any one example below may apply to a number of printing techniques including those identified here and others known in the art, such as gravure printing, Flexography printing, screen printing, offset lithography printing, dry offset printing, etc. The power sources may therefore, be uniquely printed using the same or similar equipment employed in printing magazines, packaging materials, advertisement materials, clothing, equipment, etc.

### EXAMPLES

The following examples are offered to aid in understanding the present invention and are not to be construed as limiting the scope thereof.

### Example 1

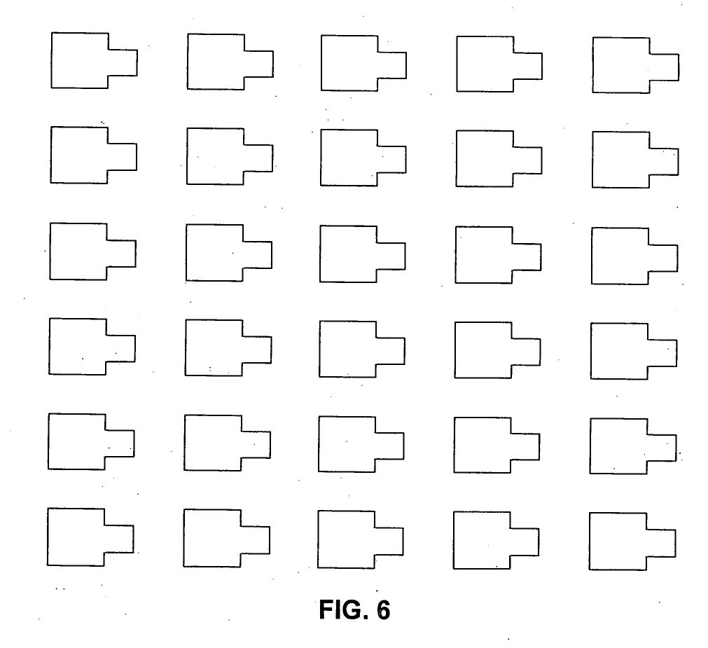

A person of ordinary skill in the art would understand screen-printing as a simple technique to overlay multi-layers of inks in registration. It may employ the use of silk screens with a photo resist mask that defines the images to be printed. An 8.5″×11″ sheet of ITO coated 3 mil Mylar (OSC50 By CPF films Canoga Park Calif.) was used as the substrate. It had a conductivity of 50Ω/cm and transparency of over 85% in the visible range. A portion of the ITO was removed, using a focused beam CO₂ laser from Photomachining Corp. of Derry N.H., to define isolated square areas as the anodes (see FIG. 6).

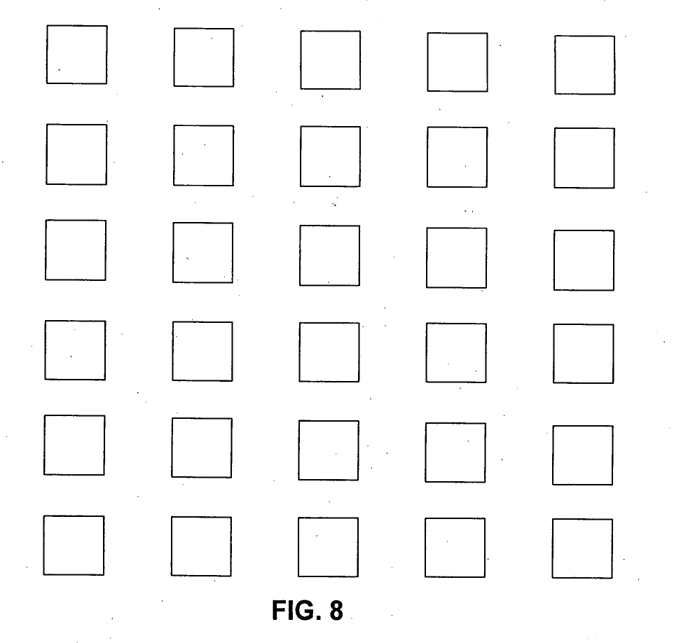

The next layer; n-type material, incorporated a dispersion of TiO₂ particles (P25 from Deggusa AG) in an acrylic resin binder (BT26 from NeoResin Wilmington Del.). The viscosity was adjusted to 10,000 cp using Rheolate 288 from Elementis Specialties Hightstown N.J. The ink was printed through a screen (320 mesh) that defined isolated square areas that registered directly on top of the isolated ITO anodes (see FIG. 8) and served as the n-type semiconducting acceptor layer.

The p-type material was a solution of poly3-octylthiophene (Rieke metals Lincoln Nebr.) in xylene and was screen printed using the same mask in registration on top of the n-type acceptor material. The latter served as the donor layer of the cell.

The hole conductor was applied next. It was made of a dispersion of 100 nm sized carbon black (Cabot Corp. Billerica Mass.) dispersed in an acrylic copolymer resin (BT100 NeoResin Wilmington Mass.). It was screen printed with a similar mask of slightly smaller dimensions, to avoid shorting the cell, in registration and on top of the p-type donor material. Insulating pads were subsequently printed between the cells to prevent them from shorting when the cathode and interconnections were printed.

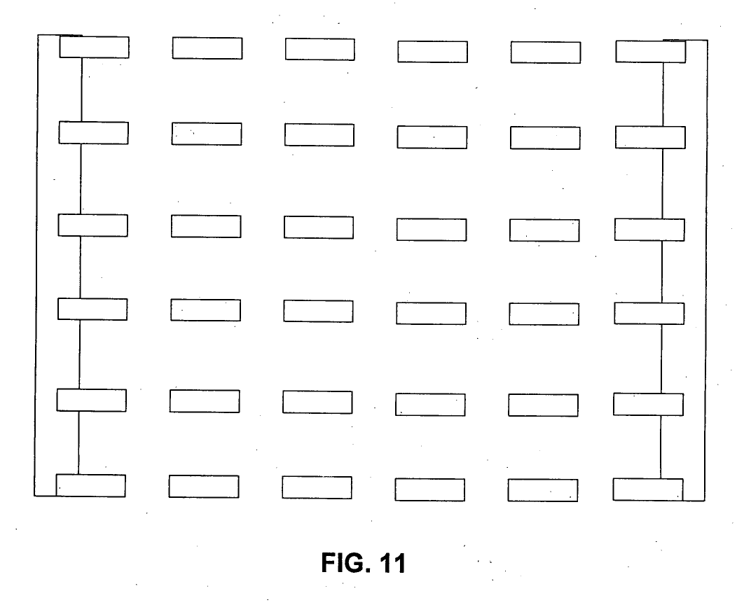

The insulating layer was a clear polymer (Eastek from Eastman Chemical Kingaport Tenn.). The final layer of the stack was a silver based ink (Dupont Wilmington Del.), which served as both the cathode of each stack as well as the series and parallel connections of the array. The cathode part was printed as squares slightly smaller than the hole conductor layer and in registration with it. The interconnects were printed from the cathode area of one cell i.e. the top; to the anode of the neighboring cell i.e. the bottom; in registration and on top of the insulating layer that was between the cell stacks. Large wide strips of this layer were also printed at each edge of the array and served as the bus lines (see FIG. 11). The resulting panel of 15 series connected cells and 20 rows supplied 5V and 20 mA of power when exposed to AM 1.5 solar condition.

### Example 2

A person of ordinary skill in the art would recognize airbrush spray painting as a method of depositing ink patterns on surfaces. It may employ the use of stencils and a spray apparatus that is well known in the art. The substrate for this technique may be any smooth object but not necessarily flat (i.e. poles as substrate would use a “Tube stencil”).

This example used an uncoated 5 mil Mylar sheet. In this example the cell was inverted, that is, the cathode was on the bottom and the transparent anode was on top. This same configuration may have been used in Example 1 using screen printing instead, wherein the top layer would have been a transparent conductive ink rather than the ITO coated substrate with a slightly different target viscosity.

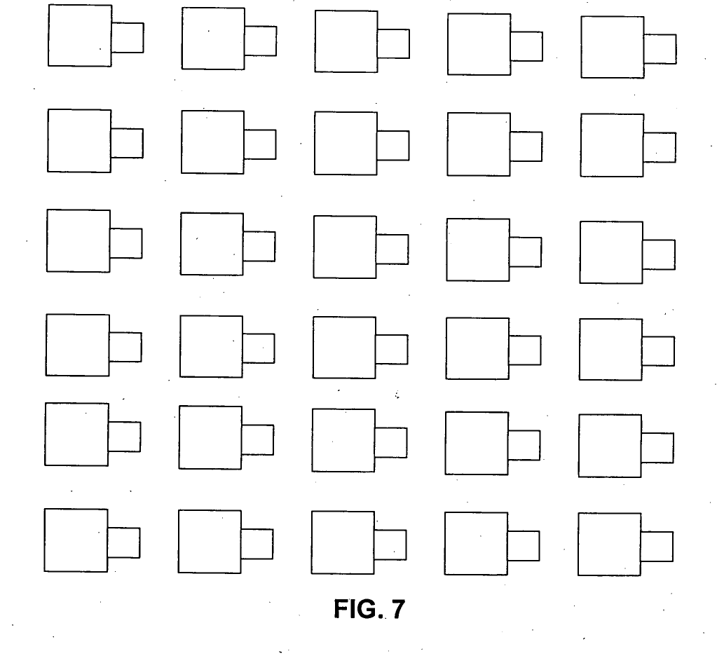

The first layer was that of a silver dispersion (3 μm mean diameter from Metalor Attleboro Mass.) in a cross-linkable acrylic co polymer dispersion (BT67 NeoResin Wilmington Del.). The ink was diluted with a solvent such as ethanol or butanol to a viscosity of 10-50 cp and was poured into the spray gun container. The stencil was affixed to the substrate and the silver ink was sprayed onto the substrate creating the pattern through the stencil. The repeated pattern was that of two squares touching where one square was about 25% of the area of its neighbor (see FIG. 7). The smaller square in the pattern was a landing pad to create the interconnection amongst the cells.

The next layer, the hole conductor (Baytron P from HC Stark Newton Mass.) was sprayed onto the silver layer with the same repeating pattern, but only that of the large squares without the smaller square neighbors as shown in FIG. 8. The next layer was composed of a 2% solution of Plexcore PM (Plextronics Pittsburgh Pa.) in Toluene. The same stencil pattern (FIG. 8) was used for this layer as the latter.

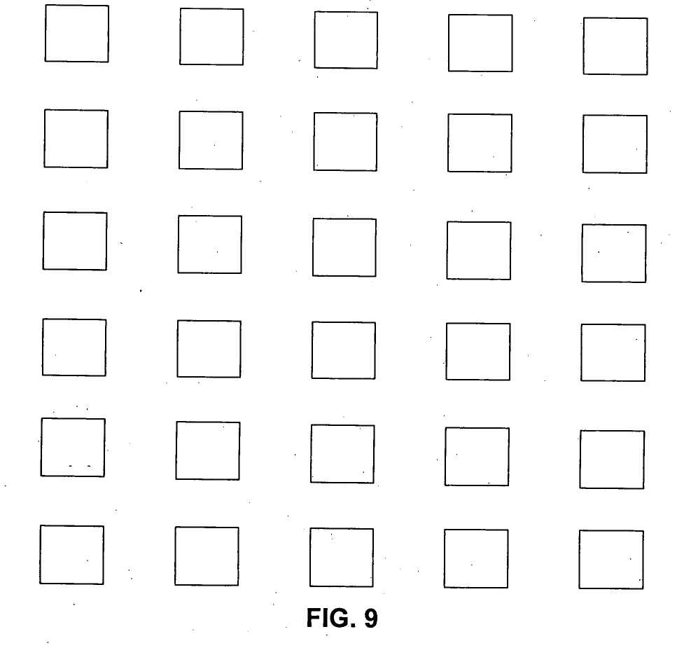

The subsequent layer was a sol gel dispersion of 13 nm particles in an alcohol water solution (Nanoxide from Solaronix Aubonne Switzerland) that was sprayed on using a similar stencil pattern, but with the squares having 50 mils shorter sides than the previous stencil (see FIG. 9). This layer was dried and then exposed to UV radiation to activate it.

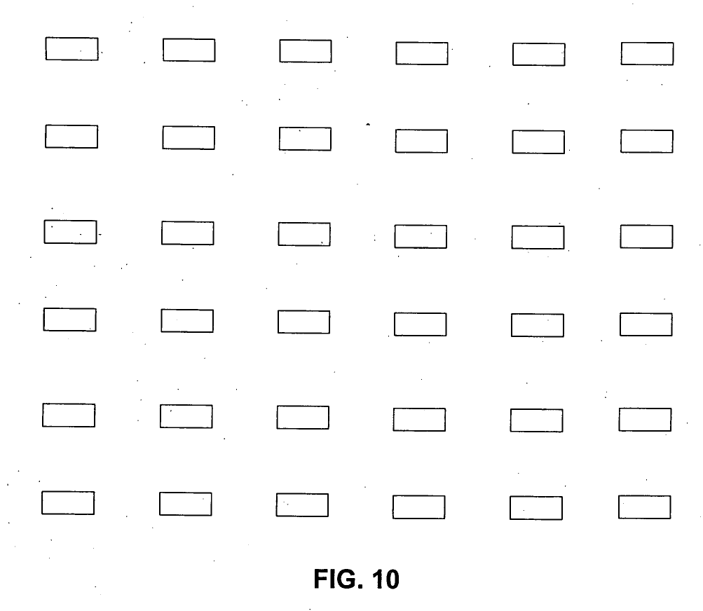

The next layer was composed of nanometer sized silver particles dispersed in an aqueous solution (Sumitomo Metal Mining Co. Tokyo Japan). It served as the transparent conducting anode. The two interconnection layers to make a panel started with an insulating enamel (Glyptal inc. Chelsea Mass.) that was stenciled between squares leaving the landing parts of the first layer exposed (see FIG. 10). The second of the interconnecting layers was the same ink as the first layer and was deposited as a bar shaped patterns that connect the top of one square to the landing pad of the adjoining square. The pattern was terminated by bus lines along both the two edges of the sheet (see FIG. 11). This sheet supplied 10V and 100 μA when exposed to AM 1.5 radiation.

### Example 3

A person of ordinary skill in the art would recognize gravure as employing a smooth cylinder that has divots in it that define the printed image. Ink may be supplied to the roll and may be squeezed off with a squeegee prior to contact with the substrate to deposit ink on it only form the area with the divots. An 8 station Gravure press was used to print solar panels onto a flexible substrate. A 3 mil roll of Mylar (J102 Dupont Del.) was used as the substrate. Ink viscosities were adjusted to 200-300 cp.

The first station deposited the transparent conductive material in the same pattern as the bottom layer of the previous example depicted in FIG. 7. The ink was a dispersion of 50 nm sized ITO flakes (from Inframat Advanced Material Farmington Conn.) in an acrylic emulsion (BT187 NeoResin Wilmington Mass.). The next layer was a dispersion of 5% 20 nm ZnO powder (from Inframat Advanced material Farmington Conn.) and 95% 20 nm TiO₂ powder (P25 Degussa) in an acrylic copolymer dispersion (BT26 NeoResin Wilmington Mass.).adjusted to a viscosity of 250 cp with ethanol. It was printed in the pattern as depicted in FIG. 8 in registration with the previous transparent conductive layer pattern leaving the landing pad area exposed.

The next station used the same exact pattern as the previous to deposit the P-type semi-conductive material. This example used copper phthalocyanine (Clariant Charlotte N.C.) dispersed in n-propanol and adjusted to a viscosity of 200 cp. The hole conducting layer was the same as used in the screen printing example (i.e. carbon black) diluted with ethanol to give a viscosity of 300 cp. The next station deposited the insulator (Eastek Eastman Chemical Kingaport Tenn.) material between the stacks so as to not short them when the interconnections were deposited. This layer was a UV curable resin and was printed using the same pattern as in the previous example (see FIG. 10).

The final station printed the cathode layer and interconnects simultaneously (see FIG. 11). The ink used was the same used for the interconnects in the previous example, i.e. silver flakes in an acrylic binder. A foot long section was then cut from the printed roll and attached to a volt meter. Upon exposure to sunlight it supplied 5V and 100 mA.

### Example 4

In another example, an 8 station gravure press may be used to print solar panels onto a flexible substrate. A 3 mil roll of Polyclad paper material available from Polyclad Technologies, Millbury, Mass., is used as the substrate. Ink viscosities are adjusted to 200-300 cp.

The first station deposits silver based conductive ink in the same pattern as the bottom layer of the previous example depicted in FIG. 7. Parmod from Parelec, Rocky Hill, N.J., was used as the base material and was adjusted to the proper viscosity by the addition of naphtha. The hole conductor was applied next made of a dispersion of 100 nm sized carbon black (available from Cabot Corp., Billerica, Mass.) dispersed in an acrylic copolymer reins (BT100 NeoResin, Wilmington, Mass.) and diluted with ethanol to give a viscosity of 300 cp. It was printed with a square pattern (see FIG. 8) of slightly smaller dimensions than the square area represented in FIG. 7 to avoid shorting the cell, in registration and on top of the square region of the cathode layer material.

The next station uses the same exact pattern as the previous to deposit the P-type semiconductive material. This example uses Copper Phthalocyanine (Clariant Charlotte N.C.) dispersed in N-Propanol and adjusted to a viscosity of 200 cp. The n type layer was applied next. It comprises a dispersion of 5% 20 nm ZnO powder (from Inframat Advanced material Farmington Conn.) and 95% 20 nm TiO₂ powder (P25 Degussa) in an acrylic copolymer dispersion (available as BT26 from NeoResin, Wilmington Mass.) adjusted to a viscosity of 250 cp with ethanol. It was printed in the pattern as depicted in FIG. 9 in registration with the previous layer pattern leaving the landing pad area of the cathode layer exposed.

The next station deposits the anode material. It is a transparent conductive ink comprising a dispersion of 50 nm sized ITO flakes (from Inframat Advanced Material, Farmington Conn. ) in an acrylic emulsion (available as BT187 from NeoResin, Wilmington Mass.).It was deposited directly onto the n type layer in the same shape (i.e. FIG. 9). The next station deposits the insulator (Eastek Eastman Chemical Kingaport Tenn.) material between the stacks so as to not short them when the interconnections are deposited. This layer is a UV curable resin and is printed using the pattern depicted in FIG. 10. The final station prints the interconnects (see FIG. 11). The ink used is the same as is used for the interconnects in the previous example i.e. silver flakes in an acrylic binder. This sheet provides an open circuit voltage of 3V and a short circuit amperage of 1 mA.

### Example 5

A person of ordinary skill in the art would recognize intaglio printing such as Flexography and letterpress as using raised images on a cylinder akin to a rotating stamp. Ink was fed to the cylinder via annilox rolls or an ink train to meter the amount of ink supplied to the printing cylinder. Ink viscosity was approximately 50-100 cp. The same patterns and inks were used as in example 3 except that the ink's viscosities were adjusted to 70 cp.

While this invention has been described as having a preferred design, the present invention can be further modified within the spirit and scope of this disclosure. This application is therefore intended to cover any variations, uses, or adaptations of the invention using its general principles. Further, this application is intended to cover such departures from the present disclosure as come within known or customary practices in the art in which this invention pertains and which fall within the limits of the appended claims.

### Example 6

The printed panel of example four was printed along with graphics containing areas with luminescent ink. The first layer to be printed under the graphics is a silver layer defining the entire region that would light up. It is made of the same ink used for the interconnects in the previous example. The insulator ink was printed next over the silver layer with openings defining the area that the electroluminescent ink would be printed. The electroluminescent ink was then printed in the areas where the silver layer is exposed. The next layer is the transparent conductor layer, which covers the electroluminescent ink and insulator areas. Silver contacts to the solar array were then printed from the bus lines to contact the bottom silver pad and top transparent conductor layer to complete the circuit. The graphics comprising the rest of the image were then printed covering the entire construction. Upon exposure to light the image lights up in the area where the electroluminescent ink was printed.

The foregoing description is provided to illustrate and explain the present invention. However, the description hereinabove should not be considered to limit the scope of the invention set forth in the claims appended here to.

What is claimed is:

1. A photovoltaic novelty item comprising:
a substrate;
a solar cell disposed on said substrate, wherein said solar cell comprises a conductor ink, an electron acceptor ink contacting said conductor ink, an electron donor ink contacting said electron acceptor ink, a conductor ink contacting said electron donor ink, and a collector ink contacting said conductor ink; and
a light emitting printed graphics in communication with said solar cell wherein said solar cell is a novelty item.

2. The photovoltaic novelty item of claim 1, further comprising at least two solar cells disposed on said substrate; an interconnection between said solar cells; and an insulator disposed between said interconnection and said substrate.

3. The photovoltaic novelty item of claim 2, further comprising a plurality of solar cells and a plurality of interconnections, wherein said interconnections are arranged in configurations selected from the group consisting of parallel, series and combinations thereof.

4. The photovoltaic novelty item of claim 1, wherein said substrate is selected from the group consisting of paper, fabric, polymeric material, and combinations thereof.

5. The photovoltaic novelty item of claim 1, wherein said light emitting printed graphics are a printed graphic on said substrate.

6. The photovoltaic novelty item of claim 1 further comprising an interconnection between said light emitting printed graphics and said solar cell.

7. The photovoltaic novelty item of claim 6 including a plurality of solar cells and a plurality of light emitting printed graphics and a plurality of interconnections, wherein said interconnections are arranged in configurations selected from the group consisting of parallel, series and combinations thereof.

8. The photovoltaic novelty item of claim 1 wherein said novelty item is a greeting card.

9. The photovoltaic novelty item of claim 1 wherein said novelty item is wrapping paper.

10. The photovoltaic novelty item of claim 1 wherein said novelty item is an advertisement.

11. The photovoltaic novelty item of claim 1 wherein said novelty item is a label.

12. The photovoltaic novelty item of claim 1 wherein said solar cell is a temporary battery.

13. The photovoltaic novelty item of claim 1 wherein said novelty item is survival gear.

14. The photovoltaic novelty item of claim 1 wherein said novelty item is a single use item.

15. The photovoltaic novelty item of claim 1 further comprising a removable cover sheet, wherein said sheet is configured to prevent exposure of said solar cell to light.

16. The photovoltaic novelty item of claim 1 further comprising a package configured to prevent exposure of said solar cell to light, wherein said solar cell is removably placed in said package.

17. A method for providing a photovoltaic novelty item comprising:
providing a substrate, wherein the substrate is a novelty item;
providing a light emitting diode on said substrate;
providing a conductor ink;
providing an electron acceptor ink;
providing an electron donor ink;
providing a conductor ink;
providing a collector ink; and
disposing on said substrate said conductor ink; said electron acceptor ink contacting said conductor ink; said electron donor ink contacting said electron acceptor ink; said conductor ink contacting said electron donor ink; and said collector ink contacting said conductor ink to form a solar cell, wherein said light emitting printed graphics are in communication with said solar cells.

18. The method of claim 17, wherein said step of disposing comprises printing said inks on said substrate using a printing method selected from the group consisting of Gravure printing, airbrush spray printing, Flexography printing, screen printing, offset lithographic printing and dry offset printing.

19. The method of claim 17 wherein said novelty item is selected from the group consisting of sundries, greeting cars, wrapping paper, packaging, bags, advertisements, advertisement goods, magazine graphics, labels, brochures, signs and combinations thereof.
